(19) United States
(12) Patent Application Publication
(10) Pub. No.: US 2014/0285223 A1
(43) Pub. Date: Sep. 25, 2014

(54) CAPACITANCE TYPE OCCUPANT DETECTION SENSOR

(71) Applicant: Denso Corporation, Kariya-city (JP)

(72) Inventor: Takashi Inoue, Kariya-city (JP)

(73) Assignee: Denso Corporation, Kariya-city (JP)

(21) Appl. No.: 14/172,094

(22) Filed: Feb. 4, 2014

(30) Foreign Application Priority Data
Mar. 21, 2013 (JP) 2013-058599

(51) Int. Cl. B60N 2/00; G01R 27/26

(52) U.S. Cl. CPC B60N 2/002; G01R 27/2605
USPC 324/688; 324/686

(57) ABSTRACT

A capacitance type occupant detection sensor includes a capacitive sensor, a reference electrode, a voltage application part, a current detector, a capacitance calculator, and a determination part. The capacitive sensor has a main electrode and is placed to a vehicle seat. The reference electrode is applied with reference voltage. The voltage application part applies detection voltage to the main electrode. The current detector detects detection current flowing through the main electrode. The capacitance calculator calculates a first capacitance between the main electrode and the reference electrode. The determination part determines an occupant of a vehicle. The capacitive sensor has a sub electrode. The determination part switches between an occupant detection mode and a wet detection mode. The capacitance calculator calculates first conductance, a second conductance, and a third conductance. The determination part determines whether the occupant exists and whether the vehicle seat is wet.

### CROSS REFERENCE TO RELATED APPLICATION

This application is based on Japanese Patent Application No. 2013-58599 filed on Mar. 21, 2013, the disclosure of which is incorporated herein by reference.

### TECHNICAL FIELD

The present disclosure relates to a capacitance type occupant detection sensor that determines a type of an occupant based on a capacitance.

### BACKGROUND

A capacitance type occupant detection sensor is disclosed in JP-A-2008-111809 (corresponding to US 2008/0100425 A1), for example. In the capacitance type occupant detection sensor, an electrode is installed into a seat of a vehicle. The capacitance type occupant detection sensor determines whether an occupant of the vehicle takes a seat or determines a type of the occupant (i.e., an adult person, a child sitting on a child restraint systems, or the like), based on a change of a capacitance between the electrode and a reference electrode (e.g., a vehicle body or the like). Hereinafter, the child restraint system is referred to as a CRS. Specifically, a relative permittivity of a detection object that is placed between electrodes is different each other. For, example, the relative permittivity of the air, the CRS, the adult person is about 1, between 2 and 5, and about 50, respectively. Therefore, the detected capacitance is changed, and the detection object is determined based on a capacitance change. The capacitance change may be detected by an impedance calculated from the amount of current and voltage between the electrodes.

A capacitive sensor installed into a seat includes a main electrode and a sub electrode. The main electrode detects a capacitance on the seat. The sub electrodes detects whether the seat is wet. It is possible to determine whether the seat is wet (corresponding to a wet state) based a conductance between the main electrode that is applied with voltage and the sub electrode that is applied with a reference voltage.

However, when the occupant of the vehicle touches a vehicle body that is applied with the reference voltage, or when the occupant touches a cigarette lighter port, a USB terminal, or a portable equipment (e.g., a mobile terminal) connected to an outlet in the vehicle, so that a grounding contact occurs, a detection circuit may be connected to the reference voltage (i.e., a vehicle grounding) through a human body. Due to a diffusion of the portable equipment, it is considered that the above case may happen more often. When the grounding contact occurs, the detected capacitance and the detected conductance are changed. Therefore, it may possible to improve accuracy about determination of the occupant and the wet state.

### SUMMARY

It is an object of the present disclosure to provide a capacitance type occupant detection sensor to improve a determination accuracy about an occupant and a wet state.

According to an aspect of the present disclosure, the capacitance type occupant detection sensor includes a capacitive sensor, a reference electrode, a voltage application part, a current detector, a capacitance calculator, and a determination part. The capacitive sensor has a main electrode and is placed to a vehicle seat. The reference electrode is applied with a reference voltage. The voltage application part applies a detection voltage to the main electrode. The current detector detects a detection current flowing through the main electrode. The capacitance calculator calculates a first capacitance including a capacitance between the main electrode and the reference electrode, based on the detection voltage and the detection current. The determination part determines an occupant on the vehicle seat based on the first capacitance. The capacitive sensor has a sub electrode that is placed apart from the main electrode in parallel. The determination part switches between an occupant detection mode and a wet detection mode. The sub electrode, in the occupant detection mode, is applied with the detection voltage. The sub electrode, in the wet detection mode, is applied with the reference voltage. The capacitance calculator, in the wet detection mode, calculates a first conductance including a conductance between the main electrode and the sub electrode, based on the detection voltage and the detection current. The capacitance calculator, in the occupant detection mode, calculates a second conductance including another conductance between the main electrode and the reference electrode, based on the detection voltage and the detection current. The capacitance calculator calculates a third conductance, which is obtained by subtracting the second conductance from the first conductance. The determination part determines whether the occupant exists and whether the vehicle seat is wet, based on the first capacitance and the third conductance.

According to the above capacitance type occupant detection sensor, it is possible to improve accuracy about determination of the occupant and the wet state.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram illustrating a configuration of a capacitance type occupant detection sensor in a present embodiment;

FIG. 2 is a sectional view illustrating a configuration of a capacitive sensor in the present embodiment;

FIG. 3 is a diagram illustrating a detailed configuration of the capacitance type occupant detection sensor in the present embodiment;

FIG. 4 is a flow chart illustrating an operation of the capacitance type occupant detection sensor in the present embodiment;

FIG. 5 is a diagram explaining occupant determination and wet determination in the present embodiment;

FIG. 6 is a diagram explaining conventional occupant determination and conventional wet determination;

FIG. 7 is a circuit diagram illustrating an equivalent circuit in a grounding contact sate in an occupant detection mode of the capacitance type occupant detection sensor in the present embodiment; and

FIG. 8 is a circuit diagram illustrating an equivalent circuit in the grounding contact state in a wet detection mode of the capacitance type occupant detection sensor in the present embodiment.

### DETAILED DESCRIPTION

Embodiments of the present disclosure will be explained with reference to the drawings. Incidentally, in each following embodiment, identical or similar parts are described by the same symbol in the drawings. It is noted that each of the diagrams used in a following explanation is a schematic diagram, and a shape of each part in the drawings is not necessary to represent the actual shape. In the following embodiment, it is supposed that the capacitive sensor is placed to an assistant driver seat, for example.

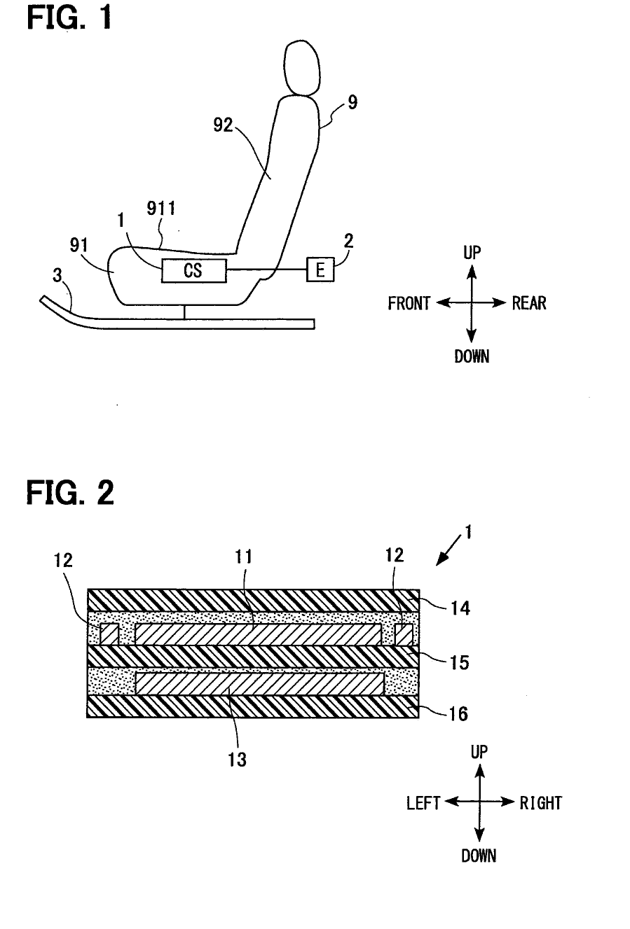

The capacitance type occupant detection sensor in the present embodiment, as described in FIG. 1, includes a capacitive sensor 1 and an occupant detection ECU 2. The capacitive sensor 1 is a film-like sensor mat, and is provided with an electrode within the film-like sensor mat. The capacitive sensor 1 is placed within a seat part 91 (e.g., within a cushion) of a seat 9 (corresponding to a vehicle seat) of a vehicle. The seat 9 has the seat part 91 having a seat surface 911 that the occupant takes a seat. The seat 9 has a seat back 92 that is placed to a vehicle rear side of the seat part 91. The capacitive sensor 1 is placed substantially parallel to the seat surface 911.

Specifically, the capacitive sensor 1, as described in FIG. 2, includes a main electrode 11, a sub electrode 12, a guard electrode 13, and film members 14 to 16. The main electrode 11 is a plate-like conductive member, and is placed on the film member 15. The film member 14 corresponds to a first film member, the film member 15 corresponds to a second film member, and the film member 16 corresponds to a third film member.

The sub electrode 12 is a plate-like conductive member, and is placed apart from the main electrode 11 in parallel. The sub electrode 12 is placed along the main electrode 11 on the film member 15, so that the sub electrode 12 is adjacent to the main electrode 11. The film member 14 is placed on the main electrode 11 and on the sub electrode 12. Thus, the main electrode 11 and the sub electrode 12 are placed between the film member 14 and the film member 15.

The guard electrode 13 is a plate-like conductive member, and is arranged on a side (corresponding to a down side of the vehicle) opposite to the seat surface 911 from the main electrode 11. The guard electrode 13 and the main electrode 11 are opposed each other. Thus, the guard electrode 13 is placed to confront the main electrode 11 through the film member 15. The film member 16 is placed in a lower part of the guard electrode 13. Thus, the guard electrode 13 is placed between the film member 15 and the film member 16.

The film members 14 to 16 are made from insulating material (e.g., PET: polyethylene terephthalate), and, for example, an adhesive agent is included between the film members 14 to 16.

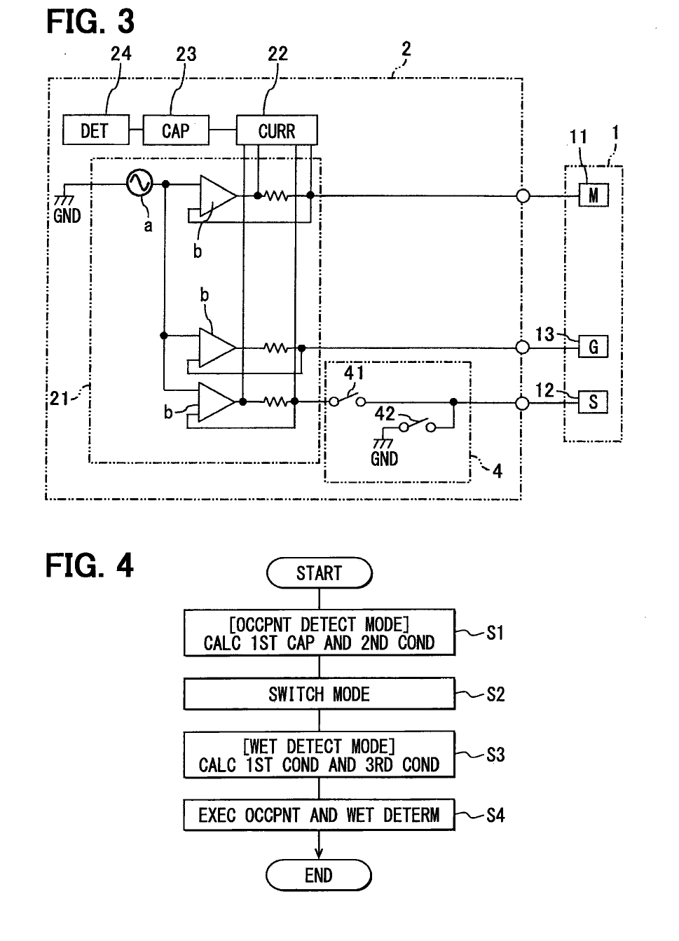

The occupant detection ECU 2 is an electronic control unit with a CPU, a memory, or the like. The occupant detection ECU 2, as described in FIG. 3, includes a voltage application part 21, a current detector 22, a capacitance calculator 23, a determination part 24, and a switch part 4, as configurations and functions.

The voltage application part 21 is connected to the vehicle grounding GND (corresponding to the reference voltage), and in addition, is connectable to each of the electrodes 11 to 13 of the capacitive sensor 1. The voltage application part 21 includes an AC source and multiple operational amplifiers b, and applies an AC voltage (corresponding to a detection voltage) to each of the electrodes 11 to 13. The operational amplifier b corresponds to a driver so that voltage equal to the detection voltage is applied to each of the electrodes 11 to 13. In an occupant detection mode described below, each of the electrodes 11 to 13 mainly provides an electric field to the vehicle body 3 (corresponding to the reference electrode). Incidentally, the vehicle body 3 is a body part of the vehicle and also configures an electrode, so that the vehicle body 3 has the reference voltage (corresponding to the vehicle grounding GND). The current detector 22 corresponds to an electric current sensor, and detects current flowing through the main electrode 11 and the sub electrode 12 by voltage application of the voltage application part 21.

The capacitance calculator 23 calculates a capacitance between predetermined electrodes based on voltage (i.e., the detection voltage), which the voltage application part 21 applies to each of the electrodes 11 to 13, and current (i.e., the detection current), which the current detector 22 detects. The capacitance is calculated based on an imaginary component (i.e., susceptance) of admittance in a current pathway in voltage application. The imaginary component is calculated from a phase shift of the voltage and the current. The capacitance calculator 23 in the present embodiment calculates susceptance and conductance (corresponding to a real number component of the admittance) in the current pathway in voltage application. Detecting the capacitance in the current pathway corresponds to calculation of the admittance (or impedance) of the current pathway. The capacitance calculator 23 is described below in detail.

The determination part 24 determines whether an adult person takes a seat or not, based on a calculation result of the capacitance calculator 23 and a predetermined threshold value. The determination part 24 controls a connection of each of the switches 41, 42 of the switch part 4, and switches an operation mode to either the occupant detection mode or the wet detection mode. Incidentally, the determination part 24 may determine a type of the occupant in more detail. For example, the determination part 24 may determine whether the occupant exists, and furthermore, whether the occupant is the adult person or the child in the CRS.

Incidentally, in the present embodiment, it is supposed that the occupant includes the adult person and the child sitting on the CRS. The adult person denotes the occupant other than the child sitting on the CRS, regardless of sex and age.

The switch part 4 switches between the occupant detection mode and the wet detection mode, and includes a first switch 41 and a second switch 42. The first switch 41 and the second switch 42 are electromagnetic switches. One end of the first switch 41 is connected to the voltage application part 21, and the other end is connected to the sub electrode 12. One end of the second switch 42 is connected to the vehicle grounding GND, and the other end is connected to the sub electrode 12. The determination part 24 instructs each of the switches 41, 42 to switch between a connection state and a disconnection state.

(Occupant Detection Mode)

In the occupant detection mode, the determination part 24 switches the first switch 41 to the connection state, and the second switch 42 to the disconnection state. Accordingly, the sub electrode 12 has the same potential with the main electrode 11, and electric fields are formed between each of the electrodes 11 to 13 and the vehicle body 3. The guard electrode 13 has the same potential with the main electrode 11 on a downside of the main electrode 11, so that the guard electrode 13 prevents the main electrode 11 from forming the electric field with the vehicle body 3 without going through the seat surface 911 of the seat 9. Therefore, the guard electrode 13 is provided so that the main electrode 11 forms the electric field on the seat 9 more surely.

The sub electrode 12 is an electrode to mainly detect wet of the seat 9 in the wet detection mode. The sub electrode 12 has the same potential with the main electrode 11 in the occupant detection mode, and forms the electric field with the vehicle body 3, similar to the main electrode 11. In the occupant detection mode, the sub electrode 12 functions similar to the main electrode 11. In the present embodiment, the capacitance, which has detected by the sub electrode 12, is also used in the occupant determination. In addition, it may be prevented that an electrical flux line which goes out from the termination (e.g., a marginal part) of the main electrode 11 spreads from the edge of the main electrode 11 to the vehicle body 3 without going through the seat 9 and the occupant. Thus, the sub electrode 12 prevents the electrical flux line of the main electrode 11 from leaking in a horizontal direction.

In the occupant detection mode, the current detector 22 detects electrical current (hereinafter, referred to as a main current) flowing through the main electrode 11, and electrical current (hereinafter, referred to as a sub current) flowing through the sub electrode 12. The main current flows through a current pathway (hereinafter, referred to as a main current pathway) including the main electrode 11 and the vehicle body 3. The sub current flows through a current pathway (referred to as a sub current pathway) including the sub electrodes 12 and the vehicle body 3. In the present embodiment, since a single electric current sensor for measuring current is used, the main current and the sub current are measured sequentially.

The capacitance calculator 23 calculates impedance of the current pathway, including the main current pathway and the sub current pathway, based on the detection voltage and the sum of the main current and the sub current. The capacitance calculator 23 calculates susceptance and conductance calculated from the calculated impedance. The susceptance corresponds to a value including a capacitance between the main electrode 11 and the vehicle body 3, and denotes a first capacitance. The conductance corresponds to a value including a conductance between the main electrode 11 and the vehicle body 3, and denotes a second conductance. The capacitance calculator 23 stores the first capacitance and the second conductance. Incidentally, the first capacitance and the second conductance may be calculated based on the main current and the detection voltage without considering the sub current pathway. In the case, the capacitance calculator 23 calculates the first capacitance from the main current and the detection voltage.

(Wet Detection Mode)

In the wet detection mode, the determination part 24 switches the first switch 41 to the disconnection state, and the second switch 42 to the connection state. Accordingly, the sub electrode 12 is connected to the vehicle grounding GND, so that the reference voltage is applied to the sub electrode 12. When the detection voltage is applied to the main electrode 11, the electric field is provided between the sub electrode 12 and the main electrode 11. Thus, a wet current pathway, including the main electrode 11 and the sub electrode 12, is formed. The current detector 22 detects current (corresponding to the detection current) flowing through the main electrode 11.

The capacitance calculator 23 calculates impedance from the detection current and the detection voltage, so that the capacitance calculator 23 calculates a conductance in the wet current pathway. The calculated conductance includes a conductance between the main electrode 11 and the sub electrode 12, and denotes a first conductance. The capacitance calculator 23 subtracts the second conductance, which is calculated and stored in the occupant detection mode, from the first conductance, so that the capacitance calculator 23 calculates a third conductance. The third conductance corresponds to a difference between the first conductance and the second conductance.

(Occupant Determination)

The determination part 24 switches from the occupant detection mode to the wet detection mode (or, from the wet detection mode to the occupant detection mode), and determines whether an occupant (i.e., an adult person) exists or not based on the first capacitance and the third conductance, which are calculated in the capacitance calculator 23. In the present embodiment, the occupant detection mode and the wet detection mode configure one detection set, and the detection set is executed at predetermined intervals.

Specifically, the occupant detection ECU 2, as described in FIG. 4, calculates the first capacitance and the second conductance in the occupant detection mode (step S1), switches the detection mode (step S2), and calculates the first conductance and the third conductance in the wet detection mode (step S3). The determination part 24 determines whether the occupant exists and whether the seat 9 is wet, based on the first capacitance and the third conductance (step S4). Incidentally, the wet detection mode may be executed before the occupant detection mode. In the case, the third conductance may be calculated in the occupant detection mode.

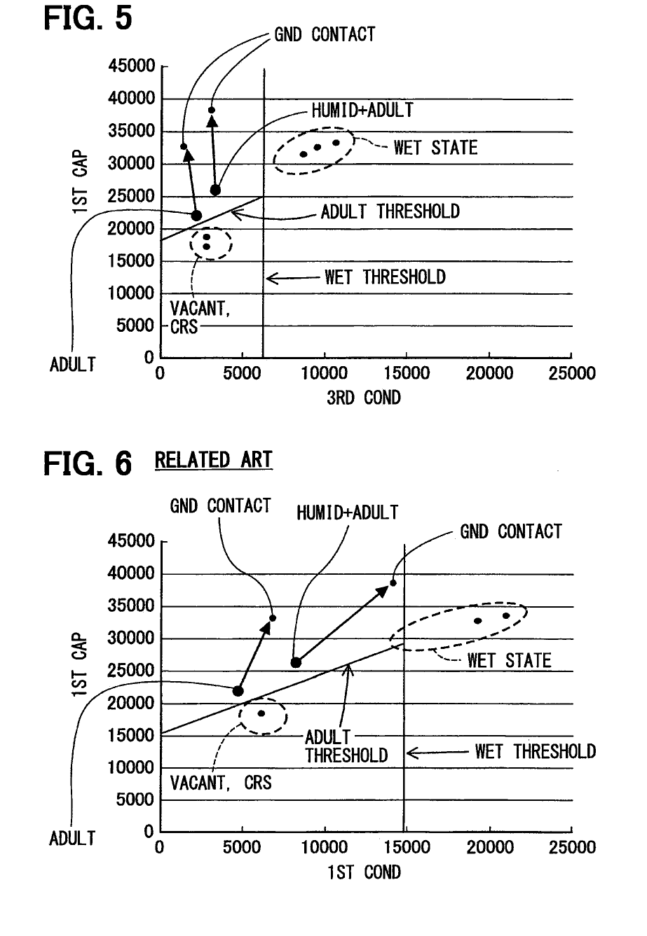

The determination part 24, as described in FIG. 5, stores a threshold value (corresponding to an adult threshold value) to determine whether the adult person takes a seat. The determination part 24 compares the adult threshold value and the first capacitance and the third conductance, so that the determination part 24 determines whether the adult person exists. The determination part 24 determines that the adult person exists in a case where the calculated first capacitance is equal to or more than a capacitance of the adult threshold value at the calculated third conductance. The determination part 24 determines that the adult person does not exist (i.e., a vacant seat or the CRS) in a case where the calculated first capacitance is less than the capacitance of the adult threshold value. Herein, the CRS denotes the child sitting on a child seat (corresponding to a car seat for a child, or the child restraint system). The adult person denotes an occupant other than the CRS (i.e., a child), regardless of sex and age.

In addition, the determination part 24 stores a threshold value (hereinafter, referred to as a wet threshold value) to determine whether the seat 9 is wet. The determination part 24 determines whether the adult person exists, as described above, and in addition, determines whether the seat 9 is wet by comparing between the wet threshold value and the first capacitance and the third conductance. In the present embodiment, the determination part 24 determines that the seat 9 is wet (corresponding to a wet state) in a case where the third conductance is equal to or more than the wet threshold value. The determination part 24 determines that the seat 9 is not wet in a case where the third conduction is less than the wet threshold value. When the determination part 24 determines that the seat 9 is wet, an occupant detection is stopped. In addition, the determination part 24 informs the occupant that the occupant detection stops, by displaying information on a display part (not shown), or the like.

The determination part 24 transmits a determination result to an airbag ECU (not described). The airbag ECU, in a case where an occupant determination result at the assistant driver seat represents that the adult person exists, permits an airbag to deploy at the assistant driver seat in a collision. On the other hand, the airbag ECU, in a case where the occupant determination result about the assistant driver seat represents that the adult person does not exist, prohibits the airbag from deploying in the assistant driver seat.

(Grounding Contact)

When the occupant contacts the vehicle grounding GND (corresponding to a case when the grounding contact happens), as described in FIG. 5, the first capacitance is increased. In the present embodiment, the third conductance, which is related to the determination of the wet state, is not increased. Thus, it is possible to determine the wet state precisely even when the grounding contact occurs. The technical effect is described below.

In a conventional capacitance type occupant detection sensor, a conductance, as represented by a horizontal axis in FIG. 5, between the main electrode 11 and the sub electrode 12 corresponds to the first conductance. Therefore, a conventional determination part determines the occupant and the wet state based on the first capacitance and the first conductance. Accordingly, as described in FIG. 6, it may happen that, when the occupant contacts the vehicle grounding GND, the first conductance increases. Especially in a high humidity state, the first conductance may approach the wet threshold value despite a state that a seat is not wet. Therefore, conventionally, an influence due to the grounding contact by the occupant is not considered, and it may be possible to improve determination accuracy in the wet state.

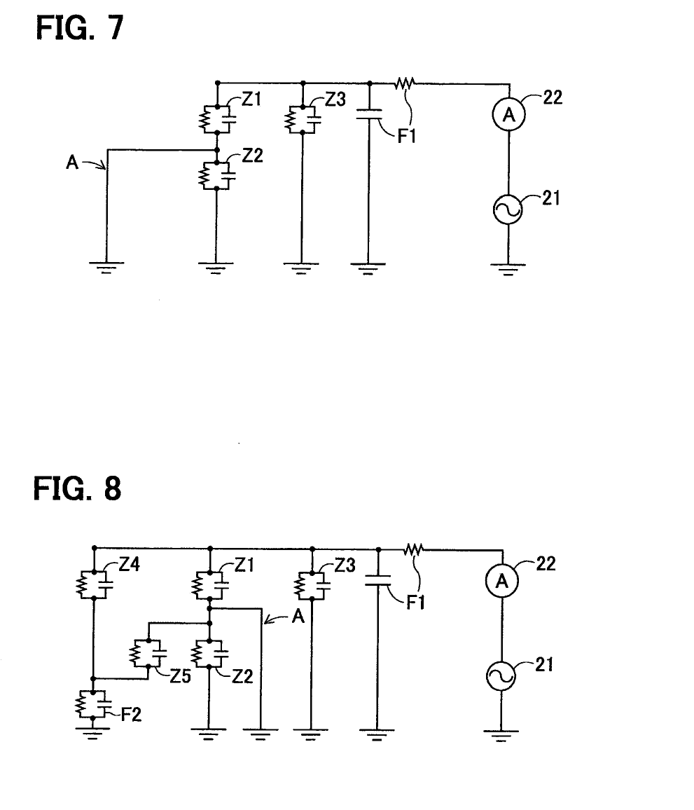

When the grounding contact occurs and the occupant detection mode is performed, as described in FIG. 7, a part between an impedance Z1 and an impedance Z2 is connected to the vehicle grounding GND through the human body (i.e., a human line A). The impedance Z1 is an impedance between the main electrode 11 and a human body. The impedance Z2 is an impedance between the human body and the vehicle body 3.

Furthermore, when the grounding contact occurs and the wet detection mode is performed, as described in FIG. 8, the part between the impedance Z1 and the impedance Z2 is connected to the vehicle grounding GND through the human line A. In FIG. 7 and FIG. 8, an impedance Z3 is an impedance between the main electrode 11 and the vehicle body 3 without including the human body. An impedance Z4 is an impedance between the main electrode 11 and the sub electrode 12. An impedance Z5 is an impedance between the sub electrode 12 and the human body. A filter F1 is a noise filter (e.g., CR filter) of the main electrode 11. A filter F2 is a noise filter of the sub electrode 12.

In the present embodiment, the third conductance is used for the occupant determination and the wet determination. The third conductance is obtained by subtracting the second conductance from the first conductance. Herein, the first conductance (corresponding to conductance of a circuit in FIG. 8) is calculated from the detection voltage and the detection current in the wet detection mode. The second conductance (corresponding to conductance of a circuit in FIG. 7) is calculated from the detection voltage and the detection current in the occupant detection mode. The third conductance corresponds to a conductance component of a synthetic impedance of the impedance Z4, the impedance Z5, and the noise filter F2.

In the third conductance, conductance in the current pathway common among the occupant detection mode and the wet detection mode is removed. The above common current pathway mainly corresponds to a pathway from the voltage application part 21 to the vehicle grounding GND through the main electrode 11 and the vehicle body 3, and in addition, the human line A. In the present embodiment, the wet determination is performed based on the third conductance, i.e., conductance in which a change of conductance in a common pathway has been removed.

As described above, in the capacitance type occupant detection sensor in the present embodiment, the occupant determination and the wet determination are performed based on the third conductance. When the occupant determination and the wet determination are performed, an impedance affected by the grounding contact (corresponding to the human line A) is removed from the third conductance. A conductance of the impedance Z4, which most strongly affects in the determination whether the wet state has occurred, is remained. Accordingly, as described in FIG. 4, even when the grounding contact occurs, a conductance component (i.e., the third conductance) for determining the wet state does not increase, and it is possible to determine the wet state accurately with taking notice of the impedance Z4. Thus, according to the present embodiment, the determination accuracy about the wet state is improved, and as a result, the determination accuracy about the occupant is also improved.

### ANOTHER EMBODIMENT

The present disclosure is not limited to the above embodiment. For example, the determination part 24 may perform the occupant determination (corresponding to determination of existence of the occupant, and a kind of the occupant) based on the first capacitance or based on a combination of the first capacitance and the second conductance. In this case, the determination part 24 refers the first capacitance or the combination of the first capacitance and the second conductance, calculated in the occupant detection mode, in order to determine the occupant, and refers the third conductance in order to determine the wet state. According to this configuration, the determination accuracy about the wet state may improve, and as a result, the determination accuracy about the occupant may also improve.

The determination part 24 may have two threshold values as the threshold value to determine the occupant. In this case, one of the threshold values may be referred for determining the existence of the occupant. The other may be referred for determining whether the occupant is an adult person. According to this configuration, it is possible to determine the occupant more in detail (i.e., no occupant, the child in the CRS, or the adult person).

According to the present disclosure, the capacitance type occupant detection sensor includes a capacitive sensor, a reference electrode, a voltage application part, a current detector, a capacitance calculator, and a determination part. The capacitive sensor has a main electrode and is placed to a vehicle seat. The reference electrode is applied with a reference voltage. The voltage application part applies a detection voltage to the main electrode. The current detector detects a detection current flowing through the main electrode. The capacitance calculator calculates a first capacitance including a capacitance between the main electrode and the reference electrode, based on the detection voltage and the detection current. The determination part determines an occupant on the vehicle seat based on the first capacitance. The capacitive sensor has a sub electrode that is placed apart from the main electrode in parallel. The determination part switches between an occupant detection mode and a wet detection mode. The sub electrode, in the occupant detection mode, is applied with the detection voltage. The sub electrode, in the wet detection mode, is applied with the reference voltage. The capacitance calculator, in the wet detection mode, calculates a first conductance including a conductance between the main electrode and the sub electrode, based on the detection voltage and the detection current. The capacitance calculator, in the occupant detection mode, calculates a second conductance including another conductance between the main electrode and the reference electrode, based on the detection voltage and the detection current. The capacitance calculator calculates a third conductance, which is obtained by subtracting the second conductance from the first conductance. The determination part determines whether the occupant exists and whether the vehicle seat is wet, based on the first capacitance and the third conductance.

According to this configuration, it is possible to utilize a value (corresponding to the third conductance) calculated by removing a conductance in the common current pathway in the occupant detection mode and the wet detection mode. The third conductance is calculated by subtracting the second conductance from the first conductance. The common current pathway may be affected by the grounding contact. In the third conductance, a conductance change in the common current pathway is removed. Thus, it is possible to perform the wet determination based on the third conductance, which includes a conductance between the main electrode and the sub electrode. According to the present embodiment, it is possible to suppress the influence of the grounding contact, and to improve the determination accuracy about the wet state. As a result, it is possible to improve the determination accuracy about the occupant.

Incidentally, the reference voltages of the reference electrode and the sub electrode may not have the same potential each other.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A capacitance type occupant detection sensor comprising:
a capacitive sensor that has a main electrode and is placed to a vehicle seat;
a reference electrode that is applied with a reference voltage;
a voltage application part that applies a detection voltage to the main electrode;
a current detector that detects a detection current flowing through the main electrode;
a capacitance calculator that calculates a first capacitance including a capacitance between the main electrode and the reference electrode, based on the detection voltage and the detection current; and
a determination part that determines an occupant on the vehicle seat based on the first capacitance,
wherein the capacitive sensor has a sub electrode that is placed apart from the main electrode in parallel,
wherein the determination part switches between an occupant detection mode and a wet detection mode,
wherein the sub electrode, in the occupant detection mode, is applied with the detection voltage,
wherein the sub electrode, in the wet detection mode, is applied with the reference voltage,
wherein the capacitance calculator, in the wet detection mode, calculates a first conductance including a conductance between the main electrode and the sub electrode, based on the detection voltage and the detection current,
wherein the capacitance calculator, in the occupant detection mode, calculates a second conductance including another conductance between the main electrode and the reference electrode, based on the detection voltage and the detection current,
wherein the capacitance calculator calculates a third conductance, which is obtained by subtracting the second conductance from the first conductance, and
wherein the determination part determines whether the occupant exists and whether the vehicle seat is wet, based on the first capacitance and the third conductance.

2. The capacitance type occupant detection sensor according to claim 1,
wherein the capacitive sensor has a guard electrode,
wherein the guard electrode is opposed to the main electrode, and
wherein the guard electrode is applied with the detection voltage.

3. The capacitance type occupant detection sensor according to claim 1,
wherein the occupant detection mode and the wet detection mode provide a detection set, and
wherein the detection set is executed at predetermined intervals.

4. The capacitance type occupant detection sensor according to claim 1,
wherein an adult person corresponds to the occupant other than a child sitting on a child restraint system, and
wherein the determination part stores:
an adult threshold value to determine whether the adult person is seated; and
a wet threshold value to determine whether the vehicle seat is wet.

5. The capacitance type occupant detection sensor according to claim 1,
wherein the capacitive sensor, which is placed to the vehicle seat, is substantially parallel to a surface of the vehicle seat.

6. The capacitance type occupant detection sensor according to claim 5,
wherein the capacitive sensor further includes film members,
wherein the main electrode and the sub electrode are placed between a first film member and a second film member, and
wherein the guard electrode is placed between the second film member and a third film member.

7. The capacitance type occupant detection sensor according to claim 6,
wherein the determination part controls two switches, which are connected to the voltage application part, the sub electrode, and a grounding, and
wherein, based on a connection state of the two switches, either the occupant detection mode or the wet detection mode is performed.
